(19) United States
(12) Patent Application Publication
(10) Pub. No.: US 2012/0257307 A1
(43) Pub. Date: Oct. 11, 2012

(54) ELECTRONIC COMPONENT AND ELECTRONIC DEVICE

(76) Inventor: Kota Tokuda, Ome-shi (JP)

(21) Appl. No.: 13/350,428

(22) Filed: Jan. 13, 2012

(30) Foreign Application Priority Data
Apr. 6, 2011 (JP) 2011-084324

(51) Int. Cl. H05K 1/00; G11B 5/48

(52) U.S. Cl. 360/245.9; 174/254; G9B/5.147

(57) ABSTRACT

According to one embodiment, an electronic component includes: an FPC wiring board in which electrical interconnections are formed on a film; a first FPC reinforcement plate which is bonded to a part of the FPC wiring board and has an opening portion; and a second FPC reinforcement plate which is bonded to another part of the FPC wiring board and has a projection which can be engaged with the opening portion of the first FPC reinforcement plate.

### CROSS REFERENCE TO RELATED APPLICATION(S)

The application is based upon and claims the benefit of priority from Japanese Patent Application No. 2011-084324 filed on Apr. 6, 2011, the entire contents of which are incorporated herein by reference.

### BACKGROUND

1. Field

Embodiments of the present invention relates to an electronic component and an electronic device.

2. Description of the Related Art

In recent years, with, for example, the increase of the communication amount, electronic devices capable of storing a large amount of data (information), such as a hard disk drive (HDD), have spread.

In hard disk drives, data (information) is recorded on or read from a disk which is coated with a magnetic material by rotating the disk at high speed and moving a magnetic head over the disk.

In electronic devices such as a hard disk drive, a flexible printed circuit board, for example, is used for data transfer or data communication.

The flexible printed circuit board is a printed circuit board which is flexible and hence can be deformed to a large extent. The flexible printed circuit board is also called a flexible circuit board or flexible printed circuits (FPC).

In this specification, the flexible printed circuit board is referred to as an FPC wiring board. And a reinforcement plate which supports and reinforces an FPC wiring board is referred to as an FPC reinforcement plate.

For example, in a hard disk drive, electronic components for controlling the hard disk drive are mounted on an FPC wiring board which is reinforced by an FPC reinforcement plate stuck to it.

To increase the mounting density of such electronic components, a technique may be employed in which two separate FPC reinforcement plates are laid on and engaged with each other with an FPC wiring board kept stuck to them and the FPC wiring board is thereby folded.

In this technique, the state that the FPC wiring board is folded is maintained in such a manner that, for example, a projection and a hook provided on the respective FPC reinforcement plates are engaged with each other.

### BRIEF DESCRIPTION OF THE DRAWINGS

A general configuration that implements the various features of embodiments will be described with reference to the drawings. The drawings and the associated descriptions are provided to illustrate embodiments and not to limit the scope of the embodiments.

FIG. 1 shows an example structure of a hard disk drive according to an embodiment;

FIG. 2 shows an example structure of an electronic component according to the embodiment;

FIG. 3 shows the electronic component according to the embodiment in which one FPC wiring board is folded;

FIG. 4 is a perspective view, as viewed from a direction that is different from the viewing direction of FIG. 3, of the electronic component according to the embodiment in which the one FPC wiring board is folded;

FIG. 5 shows an electronic component as a comparative example;

FIG. 6 shows the electronic component as the comparative example in which one FPC wiring board is folded; and

FIG. 7 is a perspective view, as viewed from a direction that is different from the viewing direction of FIG. 6, of the electronic component as the comparative example in which the one FPC wiring board is folded.

### DETAILED DESCRIPTION

According to one embodiment, an electronic component includes: an FPC wiring board in which electrical interconnections are formed on a film; a first FPC reinforcement plate which is bonded to a part of the FPC wiring board and has an opening portion; and a second FPC reinforcement plate which is bonded to another part of the FPC wiring board and has a projection which can be engaged with the opening portion of the first FPC reinforcement plate.

An embodiment will be hereinafter described with reference to the drawings.

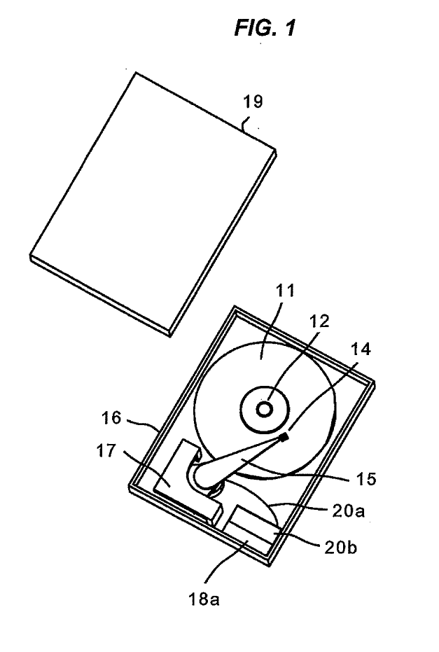

FIG. 1 shows an example structure of a hard disk drive (HDD, magnetic disk device) according to the embodiment which is an example electronic device.

Reference symbol 11 denotes a magnetic disk; 12, a spindle motor; 14, a magnetic head; 15, a head actuator; 16, a base stage; 17, a voice coil motor (VCM); 18a, an FPC reinforcement plate; 19, a top cover; and 20a and 20b, FPC wiring boards.

As mentioned above, the FPC wiring boards 20a and 20b are flexible printed circuit boards. For example, the FPC reinforcement plate 18a is stuck to the FPC wiring board 20b and thereby supports and mechanically reinforces it.

In the embodiment, the HDD has the base stage 16 which is shaped like, for example, a rectangular box having an open top. The base stage 16 houses the magnetic disk 11, the spindled motor 12, the magnetic head 14, the head actuator 15, the VCM 17, the FPC wiring boards 20a and 20b, the FPC reinforcement plate 18a, etc.

The magnetic disk 14 is supported by the base stage 16 via the spindle motor 12 and rotationally driven by the spindle motor 12.

Supported by the head actuator 15, the magnetic head 14 records or reads data on or from the magnetic disk 11 while moving over the magnetic disk 11.

Although not shown in FIG. 1, a main printed circuit board is provided on the FPC wiring board 20b. The FPC wiring board 20a electrically connects the magnetic head 14 to the main printed circuit board. That is, the magnetic head 14 and the main printed circuit board provided on the FPC wiring board 20b is electrically connected to each other by the FPC wiring board 20a. For example, a head connection portion of the FPC wiring board 20a is fixed to the head actuator 15.

Although not shown in FIG. 1, the main printed circuit board is mounted with a CPU for controlling the magnetic head 14, a memory, an HDD controller, and other circuits.

The VCM 17 is disposed between a pair of yokes which are fixed to the base stage 16. The VCM 17 and a magnet which is attached to one or both of the yokes constitute a voice coil motor. When the voice coil motor is energized, the head actuator 15 having the magnetic head 14 is moved over the magnetic disk 11, whereby information is written to or read magnetically from the magnetic disk 11.

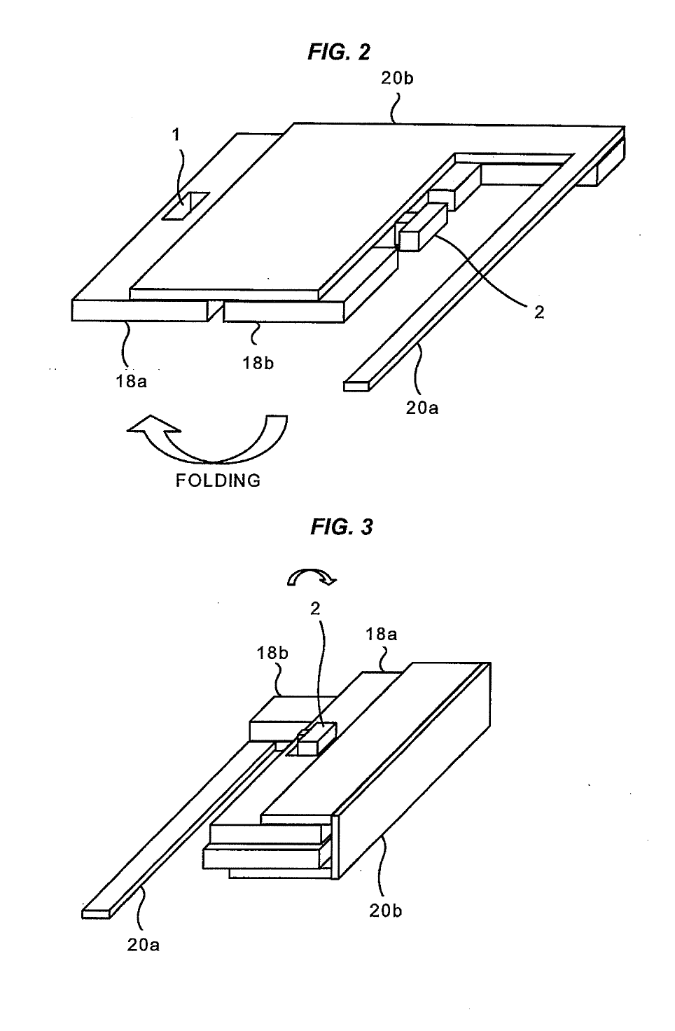

FIG. 2 shows an example structure of an electronic component according to the embodiment.

In the embodiment, the FPC wiring boards 20a and 20b are flexible printed circuit boards and, for example, constitute an integral wiring board. As shown in FIG. 2, the FPC wiring board 20b is folded. As mentioned above, the FPC wiring board 20a electrically connects the magnetic head 14 and the main printed circuit board.

A description will now be made of the flexible printed circuit board. The flexible printed circuit board is configured in such a manner that an adhesive layer is formed on a film insulator (base film) of, say, 12 to 50 μm in thickness and conductor foils of, say, 12 to 50 μm in thickness are formed on the adhesive layer. Portions other than terminal portions and soldering portions are protected being covered with an insulator.

The flexible printed circuit board can be deformed repeatedly by weak force, and its electrical characteristics are maintained even when it is deformed. For example, a polyimide film or a photosolder resist film called a coverlay is used as the insulator and the conductor foils are made of copper.

As shown in FIG. 2, the embodiment employs two reinforcement plates, that is, a first FPC reinforcement plate 18a and a second FPC reinforcement plate 18b which are made of metal or resin, for example.

As shown in FIG. 2, the first FPC reinforcement plate 18a is formed with an opening portion 1. As shown in FIG. 2, the second FPC reinforcement plate 18b is provided with a generally T-shaped projection 2.

A part of the FPC wiring board 20b is bonded to the first FPC reinforcement plate 18a with adhesive (not shown). Another part of the FPC wiring board 20b is bonded to the second FPC reinforcement plate 18b with adhesive (not shown). The FPC wiring board 20b is thus supported and mechanically reinforced by the first FPC reinforcement plate 18a and the second FPC reinforcement plate 18b.

As shown in FIG. 2, in the embodiment, the FPC wiring board 20b is folded. Then, as shown in FIG. 3, the projection 2 of the second FPC reinforcement plate 18b is inserted into and engaged with the opening portion 1 of the first FPC reinforcement plate 18a.

FIG. 3 shows the electronic component according to the embodiment in which the FPC wiring board 20b is folded.

In the embodiment, as shown in FIG. 3, the FPC wiring board 20b is folded and the first FPC reinforcement plate 18a and the second FPC reinforcement plate 18b are laid on each other. As described above, the projection 2 of the second FPC reinforcement plate 18b is inserted into and engaged with the opening portion 1 of the first FPC reinforcement plate 18a.

In the embodiment, as shown in FIG. 3, after being inserted into the opening portion 1, the projection 2 is bent (bending step) to make the engagement between the first FPC reinforcement plate 18a and the second FPC reinforcement plate 18b stronger.

As mentioned above, in the HDD, the magnetic head 14 is electrically connected to the main printed circuit board provided on the FPC wiring board 20b by the FPC wiring board 20a.

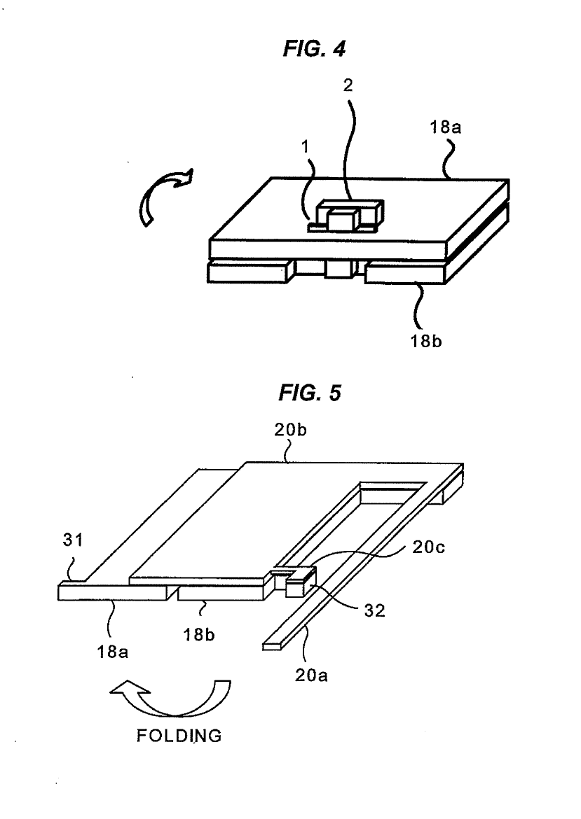

FIG. 4 is a perspective view, as viewed from a direction that is different from the viewing direction of FIG. 3, of the electronic component according to the embodiment in which the FPC wiring board 20b is folded.

FIG. 4 particularly illustrates how the first FPC reinforcement plate 18a and the second FPC reinforcement plate 18b are engaged with each other. As shown in FIG. 4, the T-shaped projection 2 which has been inserted in the opening portion 1 is bent, whereby the engagement between the first FPC reinforcement plate 18a and the second FPC reinforcement plate 18b is made stronger.

This electronic component is housed in the base stage 16 of the HDD.

FIG. 5 shows an electronic component as a comparative example. This electronic component is different from the electronic component of FIG. 2 in that, for example, the first FPC reinforcement plate 18a is provided with a projection 31 instead of the opening portion 1 and the second FPC reinforcement plate 18b is provided with a hook 32 instead of the projection 2.

Although the FPC wiring board 20b is folded as in the above embodiment, the portions that are engaged with each other are the projection 31 and the hook 32.

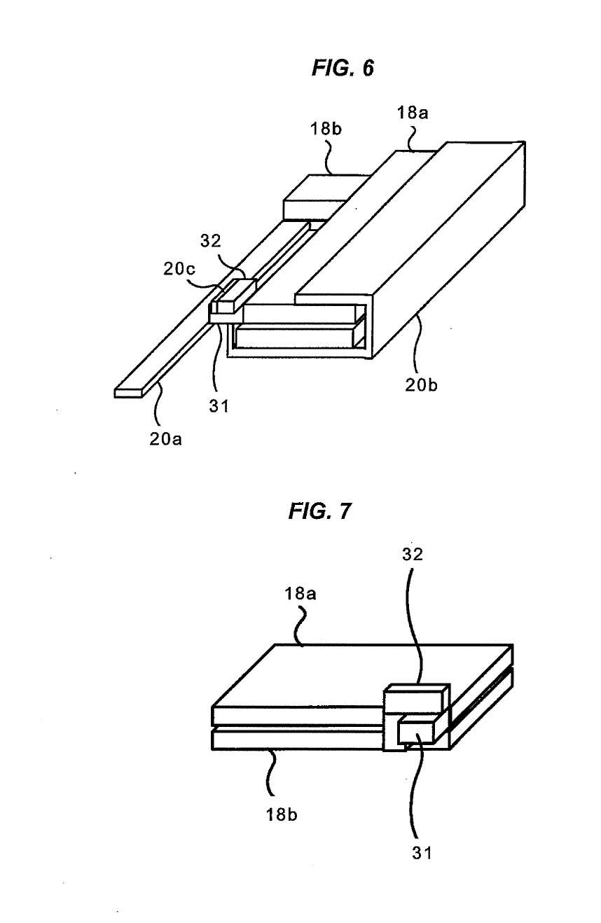

FIG. 6 shows the electronic component as the comparative example in which the FPC wiring board 20b is folded.

As shown in FIG. 6, the projection 31 and the hook 32 are engaged with each other. In this comparative example, since an engagement portion that is formed by the engagement of the hook 32 and the projection 31 is projected, the engagement portion may come into contact with and be influenced by the FPC wiring board 20a. For example, an FPC wiring board 20c is bonded to the hook 32 to reduce the influence that may be caused when the engagement portion comes into contact with the FPC wiring board 20a.

FIG. 7 is a perspective view, as viewed from a direction that is different from the viewing direction of FIG. 6, of the electronic component according to the embodiment in which the FPC wiring board 20b is folded.

As shown in FIG. 7, the first FPC reinforcement plate 18a and the second FPC reinforcement plate 18b are laid on and engaged with each other. The engagement portion which is formed by the engagement of the hook 32 of the second FPC reinforcement plate 18b and the projection 31 of the first FPC reinforcement plate 18a is projected.

In contrast to this comparative example, as shown in FIG. 2 the electronic component according to the embodiment is provided with the first FPC reinforcement plate 18a which is bonded to a part of the FPC wiring board 20b and has the opening portion 1 and the second FPC reinforcement plate 18b which is bonded to another part of the FPC wiring board 20b and has the projection 2 which can be engaged with the opening portion 1 of the first FPC reinforcement plate 18a.

The projection 2 and the opening portion 1 are engaged with each other in the manner shown in FIGS. 3 and 4, which contributes increase of the mounting density.

In the embodiment, the engagement portion which is formed by the engagement of the projection 2 and the opening portion 1 does not come into contact with the FPC wiring board 20a which serves to establish electrical connections for control of the magnetic head 14.

Therefore, the embodiment can lower the probability of occurrence of trouble that may occur in controlling the magnetic head 14 while increasing the mounting density.

Since the engagement portion which is formed by the engagement of the projection 2 and the opening portion 1 does not come into contact with the FPC wiring board 20a, it is not necessary to bond a protective member (e.g., FPC film) as used in the above comparative example to the engagement portion etc.

Therefore, a risk that a protective member peels off can be reduced. And neither a protective member nor an adhesive for bonding a protective member is necessary, which makes it possible to reduce the manufacturing costs of the electronic component and the HDD.

Since the projection 2 is generally T-shaped, it can be bent easily.

With the above configuration, the embodiment of the invention makes it possible to provide an electronic component capable of lower the probability of occurrence of trouble that may occur in controlling the magnetic head 14 while increasing the mounting density.

The invention is not limited to the above embodiment itself and, in the practice stage, may be embodied in such a manner that constituent elements are modified without departing from the spirit and scope of the invention.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic component comprising:
an FPC wiring board in which electrical interconnections are formed on a film;
a first FPC reinforcement plate which is bonded to a part of the FPC wiring board and has an opening portion; and
a second FPC reinforcement plate which is bonded to another part of the FPC wiring board and has a projection which can be engaged with the opening portion of the first FPC reinforcement plate.

2. The electronic component according to claim 1, wherein
the first FPC reinforcement plate and the second FPC reinforcement plate are engaged with each other in a state that the FPC wiring board is folded.

3. The electronic component according to claim 1, wherein
the projection is bent after being engaged with the opening portion.

4. The electronic component according to claim 1, wherein
the projection is generally T-shaped.

5. The electronic component according to according to claim 1, wherein
the projection is integral with the second FPC reinforcement plate.

6. An electronic device comprising:
a recording medium on which data can be recorded;
a data reading unit capable of reading data that is recorded on the recording medium;
an FPC wiring board in which electrical interconnections are formed which are connected to the data reading unit;
a first FPC reinforcement plate which is bonded to a part of the FPC wiring board and has an opening portion; and
a second FPC reinforcement plate which is bonded to another part of the FPC wiring board and has a projection which is configured to engage with the opening portion of the first FPC reinforcement plate.

7. The electronic device according to claim 6, wherein
the recording medium is configured so as to be capable of magnetic recording.
